(19) United States
(12) Patent Application Publication
(10) Pub. No.: US 2010/0108121 A1
(43) Pub. Date: May 6, 2010

(54) CONCENTRATING SOLAR CELL MODULE

(75) Inventor: Tai Hui LIU, Hsinchu County (TW)

Correspondence Address: HAMRE, SCHUMANN, MUELLER & LARSON, P.C., P.O. BOX 2902, MINNEAPOLIS, MN, 55402-0902, US

(73) Assignee: SOLAPOINT CORPORATION, Hsinchu County (TW)

(21) Appl. No.: 12/261,504

(22) Filed: Oct. 30, 2008

(51) Int. Cl. H01L 31/052

(52) U.S. Cl. 136/246

(57) ABSTRACT

A concentrating solar cell module without sun-tracing system is provided, wherein a transparent sphere is used as a concentrator and hence there is no need for the concentrator to trace light source, such as the Sun.

### BACKGROUND OF THE INVENTION

1. Field of the Invention

The present invention is generally related to wide-angle light collecting optical design and alignment to light source, and more particularly to a transparent sphere as light-collecting device for collecting solar or indoor light to generate power.

2. Description of the Prior Art

Energy generated from solar cell is commonly known as a better and clean energy than other power resources, such as fossil fuel power, nuclear energy power, or hydraulic power. Solar power can be much more superior when the continuing inflation of crude oil. Further, oil is bound to exhaust soon or later, but the solar power, on the other side, is exhaustless power resources compared to petrifaction power. Hence, many governments, research/development units, and private enterprises put numerous research resources into the solar power industry.

For high material cost of photovoltaic cell, and in order to cost down such that solar power can be commercialized and popular to staple commodity, now a method is provided to use optical concentrating system to reduce high material cost of using solar cell. The simplest way is to use relative large area of lens to collect lights such that a larger area of lights can be concentrated into a relative smaller area of photovoltaic cell to increase power generating efficiency. Nevertheless, due to mass volume and weight of lens, cumbersome solar power generating system is incurred. Furthermore, issues come from conventional lens optical system, such as aberration, chromatic aberration, or focus, can be raised also. Therefore, some research topics turn to other optical concentrating system to solve the issues above mentioned.

One simple solution is to use Fresnel lens to replace traditional lens. Please refer to FIG. 1, a Fresnel lens 10 focuses lights into a photovoltaic cell 13, wherein thickness of the Fresnel lens 10 can be decreased compared to the traditional lens and larger volume as well as mass of the traditional lens can be reduced significantly. Another solution, provided by Fork and Maeda, uses Cassegrain system as solar collecting system to concentrate lights. The solution they provided can be referred to US Pub. No. 2006/0231133, wherein a primary mirror and a secondary mirror are used to collect lights into photovoltaic cell. Please refer to FIG. 2, a photovoltaic cell 13 is located at bottom region of a primary mirror 11, and a secondary mirror 12 is located above the primary mirror 11. When lights are irradiated into the primary mirror 11 and reflected from the secondary mirror 12 into the photovoltaic cell 13.

Two designs of traditional concentrating solar cell module mentioned above have limitation to use high precision solar tracking system, with lens or mirror vertical or perpendicular to incident lights such that solar lights can be concentrated into chip to transform solar lights into electric power. Generally, cost on solar tracking system is about one-fifth of the total cost of all concentrating solar cell module. The more the magnification ratio of the concentrating device is, the more solar tracking precision is, and deviation tolerance decreases. For example, the Earth spins 24 hours a day, and the Sun moves relatively to the Earth about 15 degree per hour, that is 0.25 degree per minute (unit of time). When magnification ratio of the concentrating device is about 1000, the precision per minute is about 0.9 second.

Therefore, the more magnification ratio of the concentrating device is, the higher precision of the solar-tracking system is. The cost of total concentrating solar cell module will increase significantly and making the concentrating solar cell module not easy to commercialized.

### SUMMARY OF THE INVENTION

According to the issues raised from the prior art and accommodating to requirement of industrial benefit, this invention provides a simple concentrating solar cell module without using a high precision solar tracking system, wherein a transparent sphere is used as a light-collecting device.

One object of this invention is not to use high cost as well as high precision in light-tracking system or solar-tracking system.

Another object of this invention is to provide a simple solar-tracking system in concentrating solar cell module as according to this invention.

### BRIEF DESCRIPTION OF THE DRAWINGS

FIG. 1 illustrates a cross-sectional structure view of a traditional concentrating solar cell system;

FIG. 2 illustrates a cross-sectional structure view of another traditional concentrating solar cell system;

FIG. 3 illustrates a cross-sectional structure view of transparent sphere as concentrating element in concentrating solar cell module in accordance with the present invention;

FIG. 4 illustrates a cross-sectional structure view of the concentrating solar cell module mounting on a base in accordance with the present invention;

FIG. 5 illustrates a cross-sectional structure view of the concentrating solar cell module mounting on another base in accordance with the present invention;

FIG. 6A and FIG. 6B illustrate cross-sectional structure views of using multiple photovoltaic cells for the concentrating solar cell module in accordance with the present invention;

FIG. 7 illustrates a cross-sectional structure view of concentrating solar cell module mounting on a traceable C-shape arm in accordance with the present invention;

FIG. 8 illustrates a cross-sectional structure view of concentrating solar cell module mounting on a traceable base in accordance with the present invention;

FIG. 9 illustrates a cross-sectional structure view of the axis of C-shape arm in FIG. 8 that can be adjusted to any direction and angle relatively to the base in accordance with present invention; and

FIG. 10 illustrates a cross-sectional structure view of a concave lens used to increase generating power in accordance with the present invention.

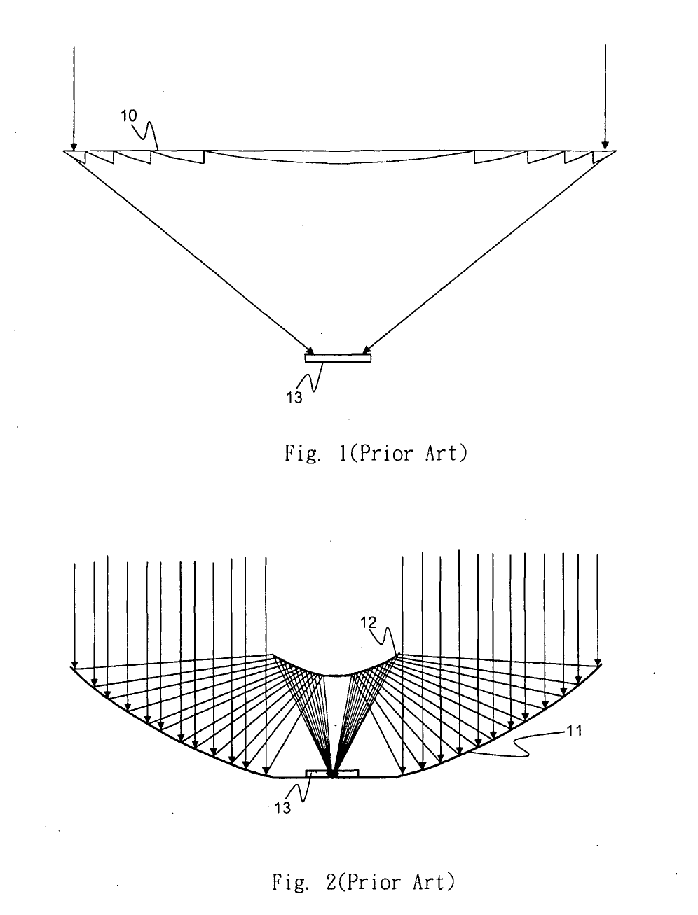

### DESCRIPTION OF THE PREFERRED EMBODIMENTS

What is probed into the invention is a concentrating solar cell module without using high precision solar tracking system. Detailed descriptions of the structure and elements will be provided in the following in order to make the invention thoroughly understood. Obviously, the application of the invention is not confined to specific details familiar to those who are skilled in the art. On the other hand, the common structures and elements that are known to everyone are not described in details as to avoid unnecessary limitations to the invention.

This invention utilizes a transparent sphere as a light-collecting element or concentrating element. When the relative position between the light source and the transparent sphere is changed, there is no need to move or rotate the concentrating element, and the light can still be focused on the other side of the transparent sphere. By using this means, the significance of orientation of light source to the transparent sphere can be decreased materially. When light source is moving, a plurality of photovoltaic cells can be placed along the moving trace of light source, or having the photovoltaic cell to trace the light source.

The traditional high precision solar-tracking systems cost much higher, however this invention can lower the cost efficiently by means of the present invention. The means of the invention provides an optoelectronic device, more particularly, a concentrating solar cell module, which comprises a concentrating element and a first photovoltaic cell to receive lights collected from the concentrating element. The concentrating element is a transparent sphere for collecting lights.

The material used for the concentrating element can be glass, quartz, plastic, acrylic, PET, PU, mCOC, epoxy, silicone, PMMA, PC, CaF crystal, or MgF crystal. The concentrating element can be manufactured by using inject-molding method. Further, the concentrating element is a hollow spherical shell filled with liquid or solid to change refractive index of the transparent sphere.

This invention further comprises a concave lens placed between the concentrating element and the photovoltaic cell for transforming lights collected by the concentrating element vertically onto the surface of the photovoltaic cell.

This invention further comprises a base to support the concentrating element and the photovoltaic cell. One embodiment to trace the light source or the solar trace is to place a second photovoltaic cell next to the first photovoltaic cell, and a third photovoltaic cell next to the second photovoltaic cell such that the first, second, and third photovoltaic cells are located on a solar track. This invention further comprises a C-shape arm and a first axis placed between two end points of the C-shape arm through the diameter of the transparent sphere. The first, second, and third photovoltaic cells can be located on the C-shape arm. The first axis is parallel to the axis of Earth rotation and the C-shape arm rotates around the first axis in a direction opposite to the Earth spin for offsetting the solar movement caused by the Earth spin. A second axis locates between the first axis and the base such that the first axis can be at any angle relative to the base.

Another embodiment to trace the light source or solar trace is to include a C-shape arm and a first axis from one end point to the other point of the C-shape arm through the diameter of the transparent sphere. A first photovoltaic cell is located on the C-shape arm. The C-shape arm has means for moving the first photovoltaic cell to any location on said C-shape arm. The first axis is parallel to the axis of Earth rotation and the C-shape arm rotates around the first axis in a direction opposite to the Earth spin for offsetting the solar movement caused by the Earth spin. A second axis locates between the first axis and the base such that the first axis can be at any angle relative to the base. A third axis is located between the first axis and the base such that the C-shape arm can face toward any direction.

This invention also provides a concentrating solar cell module, which comprises a transparent sphere for collecting lights, a photovoltaic cell for receiving lights collected from the concentrating element, and a concave lens placed between the transparent sphere and the photovoltaic cell for transforming lights collected by the transparent sphere vertically onto the surface of the photovoltaic cell. This invention further comprises means for tracking solar movement such that the photovoltaic cell moves along with the solar trace.

The following will set forth invention features, detailed explanations and embodiments with illustration of drawings.

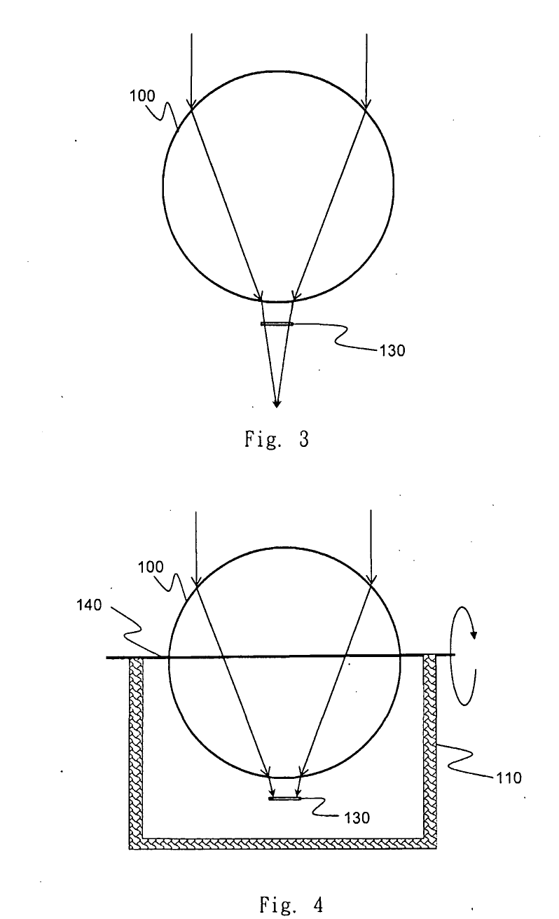

Please refer to FIG. 3, a transparent sphere 100 is used as concentrating element of this invention. The material used for the transparent sphere 100 can be glass, quartz, plastic, acrylic, PET, PU, mCOC, epoxy, silicone, PMMA, PC, CaF crystal, or MgF crystal. The transparent sphere 100 can be a hollow spherical shell filled with liquid or solid to change refractive index thereof. The transparent sphere 100 can be manufactured by using inject-molding, or grinding.

Due to the transparent sphere 100 is a perfect symmetrical lens, lights from any direction can be focused to a point opposite to the other side through the transparent sphere 100. Therefore, there is no need to rotate or move the concentrating element to align with the light source for focusing the light. When in use, a photovoltaic cell 130 is placed at or above the focal point for transforming the collected lights into electric power.

FIG. 4 illustrates a cross-sectional structure view of the concentrating solar cell module mounting on a base 110 in accordance with the present invention. The transparent sphere 100 is mounted on an axis 140 such that the photovoltaic cell 130 can rotate around the axis 140. Another embodiment is to rotate the axis 140 horizontally, and the photovoltaic cell 130 can then align to the light source at any direction. The embodiment shown in FIG. 4, is applied to indoor environment where light source is fixed, and only one to two simple rotatable axes is therefore needed to align the photovoltaic cell 130 to any direction. The simplest way of achieving that is to use two independent, vertical wheel gears.

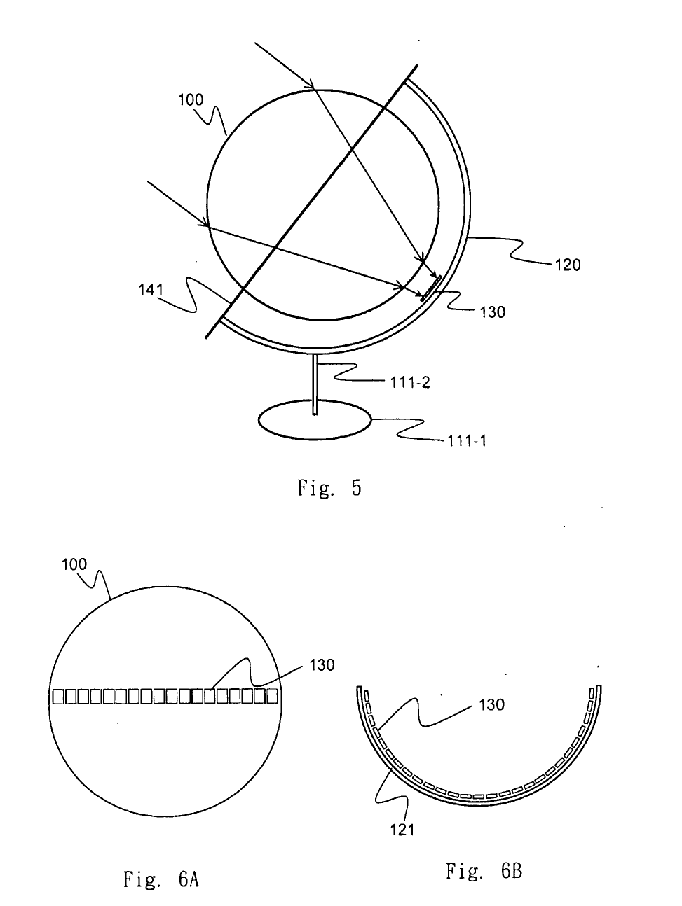

Another embodiment of this invention is shown in FIG. 5. An axis 141 is placed between two end points of a C-shape arm 120. The photovoltaic cell 130 is located on the C-shape arm 120, wherein there can be a gear or other means between the photovoltaic cell 130 and the C-shape arm to move the photovoltaic cell 130 to any location on the C-shape arm 120. A declined axis 141 is designed to trace the solar track. The declined angle of the axis 141 is equal to the latitude, such that the axis 141 is parallel to the Earth spin axis. When the Sun moves, there is only a trace perpendicular to the axis 141 as for the transparent sphere 100. A support 111-2 on the base 111-1 is to support the C-shape arm 120. The support 111-2 can be designed that the C-shape arm rotates relative to the base 111-1 and the axis 141 lies at any angle to the horizontal plane.

If the concentrating solar cell module needs to trace the Sun, a plurality of photovoltaic cells 130 can be placed at the solar track on the transparent sphere 100, as shown in FIG. 6A and 6B. One embodiment is to use a half spherical shell 121 to replace the C-shape arm such that all photovoltaic cells can be located thereon, as shown in FIG. 6B. In this embodiment, user can determine the number of photovoltaic cells to be used in accordance with the length of time necessary to generate electric power. For example, if a user determine to generate electric power for only two hours by using solar power, the Sun will move about 30 degrees. Therefore, user only needs to place a plurality of photovoltaic cells 130 in the half spherical shell in an amount equal to or more than 30 degrees. There is no tracing means for the entire concentrating system.

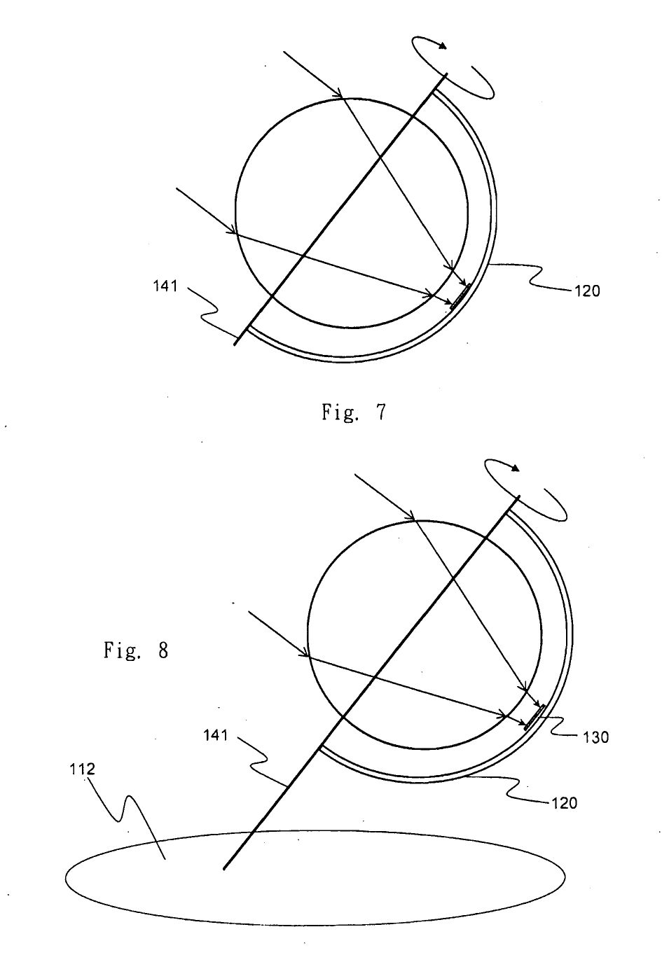

Another means to track solar movement can be referred to FIG. 7. An axis 141 parallel to the Earth spin axis, such that the C-shape arm 120 can rotate around the axis 141 to cancel or offset the Earth spin. The C-shape arm 120 can be replaced by the half spherical shell 121 as well as shown in FIG. 6B. While the Earth spin is canceled or offset, the Sun can be treated as a still or inactive celestial body.

Another embodiment can be referred to FIG. 8. The axis 141 is placed on a base 112, wherein the declined angle of the axis 141 is equal to the local latitude. The direction of the axis 141 is north while local place is in the northern hemisphere, and south while local place is in the southern hemisphere. Another way is to face the open portion of the C-shape arm 120 to the south while local place is in the northern hemisphere, and to the north in the southern hemisphere. The purpose is to align the axis 141 parallel to the Earth spin axis. The photovoltaic cell 130 can be placed at any position on the C-shape arm 120, depending on local latitude and seasons change. When the entire system is setup, solar light can be focused into the photovoltaic cells 130. The C-shape arm 120 can rotate around the axis 141 in a direction opposite to the Earth spin, and rotation velocity shall be about 15 degrees per hour. Ways to rotate the C-shape arm 120 can be simple winding-up spring, or electronic device controller. Further, photo sensor can be combined for more accurate tracking solar movement. While spring is used, there is no power used for the C-shape arm to track solar movement. If tracking accuracy should be lowered, two or three photovoltaic cells 130 can be provided on the C-shape arm 120 to cover all solar trace.

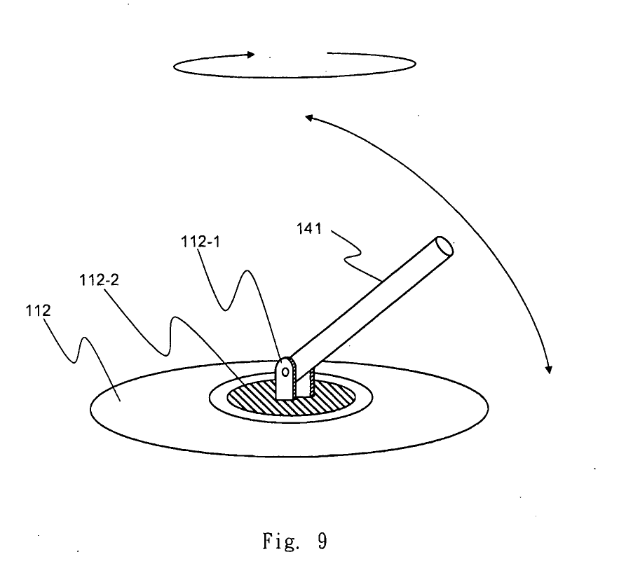

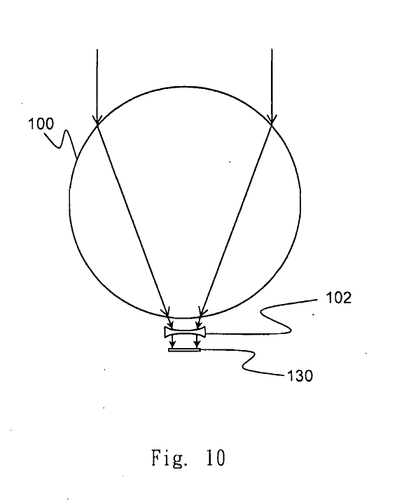

FIG. 9 illustrates a cross-sectional structure view of the axis of C-shape arm in FIG. 8 that can be adjusted to any direction and angle relative to the base in accordance with present invention. Elevating angle of the axis 141 can be adjusted by angle adjusting device 112-1. The angle adjusting device 112-1 can be two supporting walls with a screw through the axis 141 to adjust elevating angle of the axis 141. Moreover, direction of the axis 141 can be chosen by direction adjusting device 112-2. The direction adjusting device 112-2 can be concentric circle plate with an outer disk and an inner disk therein. The inner disk and outer disk can be rotated freely, and the C-shape arm 120 can be faced toward any direction.

An optical lens can be combined to the photovoltaic cell in this invention to spread light into the photovoltaic cell uniformly. Please refer to FIG. 10, a concave lens 102 is placed between the transparent sphere 100 and the photovoltaic cell 130. The concave lens is used to reflect lights from the transparent sphere into the photovoltaic cell vertically, because better power generating efficiency of the photovoltaic cell 130 is all lights incident vertically onto the surface of the cell. One result of using transparent sphere 100 is to focus a portion of lights into the photovoltaic cell 130 at an angle. The concave lens is to defocus lights to lower portion of lights parallel to surface of the photovoltaic cell 130.

This invention, can be all possible combination and portfolio of above mentioned embodiments, and any combination or portfolio shall be construed as a part of this invention. Every detailed combinations and portfolio do not recite hereinafter.

By using means of this invention, a concentrating solar cell module with simple and low cost solar-tracking system can be accomplished, wherein material volume of concentrating element does not have to move or rotate to track light source or the Sun. While light source moves, a plurality of photovoltaic cells can be placed on the predict trace opposite to the light source, such that lights can be irradiated onto the plurality of photovoltaic cells in sequence when light source moves. Another way is to move smaller and lighter photovoltaic cell to track light source; that is, the photovoltaic cell is moved along with the movement of light source. When light source is the Sun, due to the solar track is predictable, a simple tracking mechanism can be designed in this invention. Because of no high precision of solar-tracking system, a concentrating solar cell module with simple and low cost solar-tracking system can be accomplished. Hence, low cost concentrating solar cell module can be provided in this invention.

Furthermore, a small solar power generating device can be provided in this invention. Temporary or emergency power can be provided for mobile electronics.

Obviously many modifications and variations are possible in light of the above teachings. It is therefore to be understood that within the scope of the appended claims the present invention can be practiced otherwise than as specifically described herein. Although specific embodiments have been illustrated and described herein, it is obvious to those skilled in the art that many modifications of the present invention may be made without departing from what is intended to be limited solely by the appended claims.

What is claimed is:

1. A concentrating solar cell module, comprising:
a concentrating element, being a transparent sphere for collecting lights; and
a first photovoltaic cell for receiving lights from said concentrating element.

2. The concentrating solar cell module according to claim 1, wherein the material of said concentrating element is glass, quartz, plastic, acrylic, PMMA, PC, CaF crystal, or MgF crystal.

3. The concentrating solar cell module according to claim 2, wherein said collecting element is made by using inject-molding.

4. The concentrating solar cell module according to claim 1, wherein said collecting element is hollow spherical shell filled with liquid or solid to change refractive index of said transparent sphere.

5. The concentrating solar cell module according to claim 1, further comprising a base to support said collecting element and said photovoltaic cell.

6. The concentrating solar cell module according to claim 5, further comprising a second photovoltaic cell placed next to said first photovoltaic cell.

7. The concentrating solar cell module according to claim 6, further comprising a third photovoltaic cell placed next to said second photovoltaic cell such that said first, second, and third photovoltaic cells are located on a solar track.

8. The concentrating solar cell module according to claim 5, further comprising a C-shape arm and a first axis from one end point to the other point of said C-shape arm through the diameter of said transparent sphere.

9. The concentrating solar cell module according to claim 8, wherein said first, second, and third photovoltaic cells are located on said C-shape arm.

10. The concentrating solar cell module according to claim 9, wherein said first axis is parallel to the axis of Earth rotation and said C-shape arm rotates around said first axis in a direction opposite to the Earth spin for offsetting the solar movement caused by the Earth spin.

11. The concentrating solar cell module according to claim 10, wherein a second axis locates between said first axis and said base such that said first axis can be at any angle relative to said base.

12. The concentrating solar cell module according to claim 1, further comprising a C-shape arm and a first axis from one end point to the other point of said C-shape arm through the diameter of said transparent sphere.

13. The concentrating solar cell module according to claim 12, wherein said first photovoltaic cell is located on said C-shape arm.

14. The concentrating solar cell module according to claim 13, wherein said C-shape arm has means for moving said first photovoltaic cell to any location on said C-shape arm.

15. The concentrating solar cell module according to claim 12, wherein said first axis is parallel to the axis of Earth rotation and said C-shape arm rotates around said first axis in a direction opposite to the Earth spin for offsetting the Sun movement caused by the Earth spin.

16. The concentrating solar cell module according to claim 15, wherein a second axis locates between said first axis and said base such that said first axis can be at any angle relative to said base.

17. The concentrating solar cell module according to claim 16, wherein a third axis is located between said first axis and said base such that said C-shape arm can face toward any direction.

18. A concentrating solar cell module, comprising:
a transparent sphere for collecting lights;
a photovoltaic cell for receiving lights collected from said transparent sphere; and
a concave lens placed between said transparent sphere and said photovoltaic cell for transforming lights collected by said transparent sphere vertically onto the surface of said photovoltaic cell.

19. The concentrating solar cell module according to claim 18, further comprising means for tracking solar movement such that said photovoltaic cell moves along with the solar trace.

20. An optoelectronic device, comprising:
a transparent sphere for collecting lights; and
a photovoltaic cell for receiving lights collected from said transparent sphere to generate electric power.
